(19) United States
(12) Patent Application Publication
(10) Pub. No.: US 2026/0019052 A1
(43) Pub. Date: Jan. 15, 2026

(54) WIDE BAND AMPLIFIER WITH BULK RESISTANCE

(71) Applicant: TEXAS INSTRUMENTS INCORPORATED, Dallas, TX (US)

(72) Inventors: Radhika Juluri, Bangalore (IN); Meghna Agrawal, Bangalore (IN); Debapriya Sahu, Bangalore (IN); Rohit Chatterjee, Bangalore (IN); Prakhar Agrawal, Bangalore (IN); Srinivas Veeramreddi, Bengaluru (IN); Vimal Edayath, Bangalore (IN)

(21) Appl. No.: 19/069,428

(22) Filed: Mar. 4, 2025

(30) Foreign Application Priority Data
Jul. 12, 2024 (IN) 202441053406

(51) Int. Cl. H03F 3/45; H03F 1/26

(52) U.S. Cl. CPC H03F 3/45475; H03F 1/26; H03F 3/45179; H03F 2200/06; H03F 2200/294

(57) ABSTRACT

An integrated circuit includes a first transistor and a second transistor. A first current path terminal of the second transistor is coupled to a reference voltage terminal. A first current path terminal of the first transistor is coupled to a second current path terminal of the second transistors. A second current path terminal of the first transistor is coupled to a first differential output terminal. A control terminal of the second transistor is coupled to a first differential input terminal. The integrated circuit includes a first resistor with a first terminal and a second terminal. The first terminal is coupled to the bulk terminal of the first transistor, and the second terminal is coupled to the reference voltage terminal. The first resistor is disposed in a dielectric layer above the first and second transistors.

### REFERENCE TO RELATED APPLICATIONS

This application claims the benefit of Indian Provisional Application Number 202441053406, filed on Jul. 12, 2024, titled “RX-TX PORT COMBINED WIDE BAND LNA & PA USING BULK RESISTANCE IN PA” the contents of which are hereby incorporated by reference in their entirety.

### TECHNICAL FIELD

The present disclosure relates generally to an electronic system, and, in particular embodiments, to a wide band amplifier with bulk resistance.

### BACKGROUND

Amplifiers are common components in many fields, such as in the field of communication circuitry. In some cases, amplifiers are implemented with a wide operating bandwidth.

### SUMMARY

In accordance to an embodiment, an integrated circuit including: a first transistor disposed in or above a semiconductor substrate and having a control terminal, a first current path terminal, a second current path terminal, and a bulk terminal, where the second current path terminal of the first transistor is coupled to a first differential output terminal of a pair of differential output terminals; a second transistor disposed in or above the semiconductor substrate and having a control terminal, a first current path terminal, a second current path terminal, and a bulk terminal, where the control terminal of the second transistor is coupled to a first differential input terminal of a pair of differential input terminals, where the first current path terminal of the first transistor is coupled to the second current path terminal of the second transistor, and the second current path terminal of the second transistor is coupled to a reference voltage terminal; and a first resistor having a first terminal and a second terminal, where the first terminal of the first resistor is coupled to the bulk terminal of the first transistor, and the second terminal of the first resistor is coupled to the reference voltage terminal, and where the first resistor is disposed in a dielectric layer that is above the first and second transistors.

In accordance to an embodiment, an amplifier, including: first and second output terminals; first and second input terminals; a semiconductor substrate; a first transistor disposed in or above the semiconductor substrate and having first and second current path terminals, a bulk terminal, and a control terminal, the second current path terminal of the first transistor coupled to the first output terminal; a second transistor disposed in or above the semiconductor substrate and having first and second current path terminals, a bulk terminal, and a control terminal, where the first current path terminal of the first transistor is coupled to the second current path terminal of the second transistor, and where the control terminal of the second transistor is coupled to the first input terminal; a first resistor disposed in a dielectric layer that is above the semiconductor substrate, the first resistor having a first terminal coupled to the bulk terminal of the first transistor, and a second terminal, where, from a top view, the first resistor is disposed between the first and second transistors in a first direction; a third transistor disposed in or above the semiconductor substrate and having first and second current path terminals, a bulk terminal, and a control terminal, where the control terminal of the third transistor is coupled to the control terminal of the first transistor; a fourth transistor disposed in or above the semiconductor substrate and having first and second current path terminals, a bulk terminal, and a control terminal, where the second current path terminal of the fourth transistor is coupled to the first current path terminal of the third transistor; and a second resistor disposed in the dielectric layer and having a first terminal coupled to the bulk terminal of the third transistor, and a second terminal, where, from the top view, the first resistor is disposed between the third and fourth transistors in the first direction, and where, from the top view and in a second direction perpendicular to the first direction, the first transistor and the second transistor are each laterally offset from the third transistor and the fourth transistor, respectively, by a first distance.

In accordance to an embodiment, a circuit including: an antenna terminal; a first amplifier having an input coupled to the antenna terminal; a balun; a switch coupled between the balun and the antenna terminal; and a second amplifier having an output coupled to the antenna terminal through the balun and the switch, and where the output of the second amplifier is coupled to the input of the first amplifier through the balun and the switch, the second amplifier including: a first transistor pair having a first differential input terminal, a first differential output terminal, a first bulk terminal, and a second bulk terminal, where the first bulk terminal of the first transistor pair is coupled to a reference voltage terminal; a second transistor pair coupled to the first transistor pair, the second transistor pair having a second differential input terminal, a second differential output terminal, a first bulk terminal, and a second bulk terminal, where the first bulk terminal of the second transistor pair is coupled to the reference voltage terminal; a first resistor having a first terminal coupled to the second bulk terminal of the first transistor pair, and a second terminal coupled to the reference voltage terminal; and a second resistor having a first terminal coupled to the second bulk terminal of the second transistor pair, and a second terminal coupled to the reference voltage terminal, where the first and second differential output terminals are coupled to the balun.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a transceiver with a transmit (Tx) circuitry, a receive (Rx) circuitry, and an antenna;

FIG. 2 illustrates a circuit of an amplifier with bulk resistance;

FIG. 3 illustrates a top view of the amplifier of FIG. 2 having resistors coupled between bulk terminals of transistors and a reference voltage;

FIGS. 4-6 illustrate cross-sectional views of a semiconductor device with transistors and associated resistors from FIGS. 2-3;

FIG. 7 illustrates a system with a transceiver including an impedance and bandwidth matching system; and

FIG. 8 shows a graph of the simulated reflection coefficient of the system of FIG. 7.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments herein relate to an amplifier using bulk resistance to improve the operating bandwidth.

Wireless communication systems benefit from operating over wide instantaneous bandwidths. In particular, port-combined transceivers can employ a shared antenna port for both transmit (Tx) and receive (Rx) operations, enabling wide band operation without requiring separate ports for each function. Wide band operation enables higher data transfer rates, reduced latency, and increased capacity and connectivity. However, as power amplifiers (PA) and low-noise amplifier (LNA) in port-combined transceivers support wider bandwidths, several challenges may arise that impede operation.

For example, a transmitting amplifier and a low-noise amplifier (LNA) for reception can share a common port in a transceiver that is connected to an antenna, facilitating operation in either a Tx mode or a Rx mode. However, during Rx mode, the transmitting amplifier can degrade the input impedance of the LNA in wide bandwidth applications. In some implementations, capacitive loading associated with the transmitting amplifier can limit the bandwidth of the LNA, thereby constraining overall transceiver performance in Rx mode. Accordingly, techniques for reducing the quality factor (Q) of the transmitting amplifier over a wide bandwidth, as observed at the LNA input, can improve the bandwidth of port-combined transceivers.

Various aspects described herein relate to an amplifier that includes a resistance between a bulk terminal (or body terminal) of one or more transistors and a reference voltage terminal (or ground terminal) to reduce the quality factor (Q-factor) of the amplifier and decrease the insertion loss in the receive mode over a broad bandwidth. Some techniques described herein provide an arrangement in which a spacing between transistors within a semiconductor substrate establishes an impedance greater than the resistance between the bulk terminal of the transistors and the reference voltage terminal. Accordingly, crosstalk between the transistors is mitigated, and voltage couples through the resistance, thereby reducing the capacitive loading of the amplifier as observed by the LNA when the LNA is configured for reception.

The resistance can be implemented using one or more resistors formed by conductive traces within a dielectric layer of an interconnect structure above the semiconductor substrate. Accordingly, vias or wires can connect bulk terminals of the transistors to corresponding resistors, which in turn connect to the reference voltage terminal. In some embodiments, the resistors can be poly-silicon resistors. This arrangement may advantageously provide a compact footprint for the amplifier without introducing or using additional processing steps to form a deep well (such as a deep n-well or deep p-well) to reduce the capacitive loading of the amplifier. Thus, in some embodiments, a manufacturing process without deep n-well or deep p-well may be used while still mitigating crosstalk between the transistors. Aspects described herein can benefit Wifi applications, for example, across the 5 gigahertz (GHz) to 7 GHz band, as well as other wireless communications protocols, such as ultra-wideband (UWB), such as using IEEE 802.15.4z.

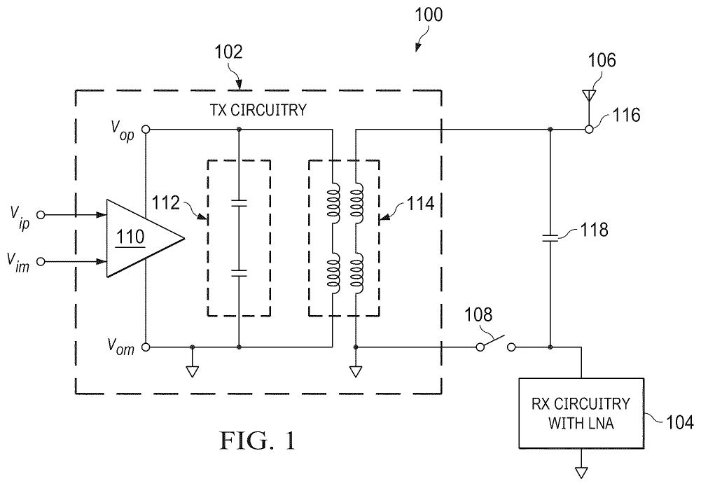

FIG. 1 shows a transceiver 100 with a transmit (Tx) circuitry 102, a receive (Rx) circuitry 104, and an antenna 106.

The Tx circuitry 102 includes an amplifier 110 (also referred to as a power amplifier or a transmit amplifier) having differential input terminals, Vip, Vin, and having differential output terminals, Vop, Vom. A pair of capacitors 112 are connected to one another in series between the output terminals (Vop, Vom) of amplifier 110. The pair of capacitors 112 are connected in parallel with a balun 114 (also referred to as a transformer). A switch 108 is connected between the Tx circuitry 102 and the Rx circuitry 104 to facilitate either a Rx mode or a Tx mode of operation with the antenna 106. Furthermore, a capacitor 118 is coupled between the antenna 106 and the Rx circuitry 102. Accordingly, a signal to and or from the antenna 106 can couple through two separate branches: one including capacitor 118 to the Rx circuitry 104 and another through balun 114 to the Tx circuitry 102.

In the Tx mode, the switch 108 is closed connecting the Tx circuitry 102 to the antenna 106 through an antenna terminal 116 (such as an input/output pin). The pair of capacitors 112 are configured as part of a matching network together with the balun 114 to optimize power transfer from the amplifier 110 to the antenna 106. The balun 114 can facilitate signal conversion from the amplifier 110 to the antenna 106 to optimize power transfer to the antenna 106. In the Tx mode, the Rx circuitry 104 can be in a deactivated or non-receiving state.

In the Rx mode, the switch 108 is open and the Rx circuitry 104 that includes the LNA can be activated and connected to the antenna 106 by the antenna terminal 116. Accordingly, the transceiver 100 can be described as a port-combined transceiver since the antenna 106 is connected to both the Tx circuitry 102 and the Rx circuitry 104 by the antenna terminal 116 that is common to both circuits. However, in broad band applications, the balun 114, the pair of capacitors 112, and the amplifier 110 may act as a load with respect to the Rx circuitry 104 in the port-combined configuration, thereby introducing residual impedance effects that degrade the LNA performance of the Rx circuitry 104.

In particular, the amplifier 110 can present a capacitive load at the antenna terminal 116 (through the pair of capacitors 112 and balun 114) shared with an input of the LNA, which affects the input impedance of the LNA and reduces its effective bandwidth. Even when switch 108 is open, parasitic capacitance from the Tx circuitry 102 can allow coupling or noise into the receive path, which may increase insertion loss and reduce the effective gain of the LNA. While the switch 108 may provide isolation between the Tx circuitry 102 and the Rx circuitry 104, at high frequencies in broad bandwidth application, parasitic capacitance and finite switch isolation can allow residual coupling between the circuits. Further, the impedance presented by the Tx circuitry 102 to the antenna terminal 116 can cause reflection and mismatch effects that degrade signal transfer from antenna 106 to the LNA of the Rx circuitry 104. These effects may collectively contribute to increased noise figure, reduced signal amplification, and potential receiver desensitization in the receive path.

As discussed further herein, loading effects of the Rx circuitry 104 by the Tx circuitry 102 can be minimized by adding bulk resistance to the amplifier 110. For example, a resistor can be added between a bulk terminal of a transistor of the amplifier 110 and a reference voltage (such as ground or bulk ground). By adding the resistor, bulk current from the transistor of the amplifier 110 may pass through the resistor before reaching the reference voltage. The added series resistance may reduce loading effects from capacitance of the transistor, as seen by the Rx circuitry 104, is minimized and the operating bandwidth of the Rx circuitry 104 is enhanced.

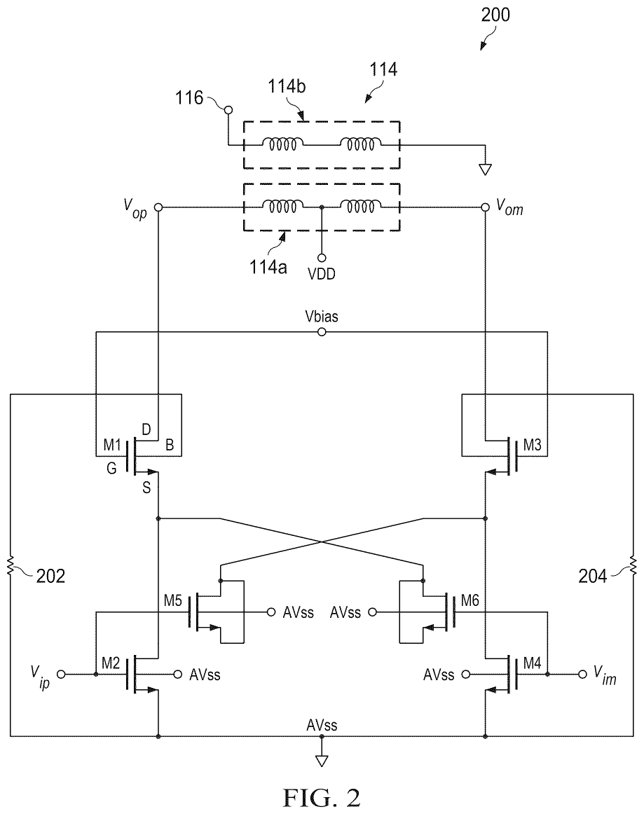

FIG. 2 shows a circuit 200 of an amplifier with bulk resistance.

The circuit 200 shows features of the amplifier 110 of FIG. 1. The circuit 200 includes a first transistor M1 and a second transistor M2 configured in a first transistor pair. A third transistor M3 and a fourth transistor M4 are configured in a second transistor pair. A fifth transistor M5 and a sixth transistor M6 are configured in a third transistor pair and coupled between the first transistor pair and the second transistor pair.

The circuit 200 has a first input terminal Vip (also referred to as a first differential input terminal), and a second input terminal Vim (also referred to as a second differential input terminal) of a pair of differential input terminals. In some embodiments, the first and second input terminals Vip, Vim are excited with a differential signal from a signal source. The circuit 200 also has a first output terminal Vop and a second output terminal Vom. In some embodiments, the first output terminal Vop is a non-inverting output of the amplifier 110 and the second output terminal Vom is an inverting output of the amplifier 110.

The first transistor M1 has a first current path terminal, a second current path terminal, a bulk terminal, and a control terminal. In some embodiments, the first transistor M1 is a metal-oxide-semiconductor (MOSFET) transistor of an n-type, and the first current path terminal is a source terminal (labeled “S” in FIG. 2), the second current path terminal is a drain terminal (labeled “D” in FIG. 2), the control terminal is a gate terminal (labeled “G” in FIG. 2), and the bulk terminal is a body terminal (labeled “B” in FIG. 2). The second current path terminal of the first transistor is coupled to the first output terminal Vop.

The second transistor M2 has a first current path terminal, a second current path terminal, a bulk terminal, and a control terminal. In some embodiments, the second transistor M2 is a MOSFET transistor of an n-type, and the first current path terminal is a source terminal, the second current path terminal is a drain terminal, the control terminal is a gate terminal, and the bulk terminal is a body terminal. The first current path terminal of the first transistor M1 is coupled to the second current path terminal of the second transistor M2. The control terminal of the second transistor M2 is coupled to the first input terminal Vip. The first current path terminal and the bulk terminal of the second transistor M2 are coupled to a reference voltage terminal AVss (such as a voltage or ground).

The third transistor M3 has a first current path terminal, a second current path terminal, a bulk terminal, and a control terminal. In some embodiments, the third transistor M3 is a MOSFET transistor of an n-type, and the first current path terminal is a source terminal, the second current path terminal is a drain terminal, the control terminal is a gate terminal, and the bulk terminal is a body terminal. The control terminal of the third transistor M3 is coupled to the control terminal of the first transistor M1. The second current path terminal of the third transistor M3 is coupled to the second output terminal Vom. The control terminal of the first and third transistors M3 are connected to a voltage bias terminal Vbias. The voltage bias terminal Vbias can be configured to provide a bias voltage to the first and third transistors M1, M3 such that the differential signal at the first input terminal Vip and the second input terminal Vim coupled respectively through the second and fourth transistors M2, M4 is amplified.

The fourth transistor M4 has a first current path terminal, a second current path terminal, a bulk terminal, and a control terminal. In some embodiments, the fourth transistor M4 is a MOSFET transistor of an n-type, and the first current path terminal is a source terminal, the second current path terminal is a drain terminal, the control terminal is a gate terminal, and the bulk terminal is a body terminal. The second current path terminal of the fourth transistor M4 is coupled to the first current path terminal of the third transistor M3. The control terminal of the fourth transistor M4 is coupled to the second input terminal Vim. The first current path terminal and the bulk terminal of the fourth transistor M4 are coupled to the reference voltage AVss.

The first output terminal Vop couples to a first terminal of a primary winding 114a of the balun 114, and the second output terminal Vom couples to a second terminal of the primary winding 114a. A center tap of the primary winding 114a is coupled to a supply voltage VDD. The balun 114 has a secondary winding 114b that can couple the signal from the first and second output terminals Vop, Vom to the antenna terminal 116.

The first and second transistors M1, M2 form the first transistor pair where the second transistor M2 operates as a common-source input transistor that converts the differential signal at the first input terminal Vip into a current signal. The first transistor M1 operates as a common-gate transistor, which passes this current to the first output terminal Vop while improving isolation and reducing the Miller effect. Similarly, the third and fourth transistors M3, M4 form the second transistor pair where the fourth transistor M4 converts the differential signal at the second input terminal Vim into a current signal. The third transistor M3 operates as a common-gate transistor, which passes this current to the second output terminal Vom. The first and second transistor pairs can enhance output impedance, provide gain, and improve bandwidth. The differential signal at the first and second output terminals Vop, Vom are then coupled to the primary winding 114a of the balun 114 for signal conversion. Accordingly, the first transistor M1 and the third transistor M3 form a cascode configuration that may improve the amplifier 110 gain, bandwidth, and linearity by increasing output impedance, reducing unwanted feedback, and minimizing parasitic capacitance effects for wideband and high-frequency applications.

The fifth transistor M5 has a first current path terminal, a second current path terminal, a bulk terminal, and a control terminal. In some embodiments, the fifth transistor M5 is a MOSFET transistor of an n-type, and the first current path terminal is a source terminal, the second current path terminal is a drain terminal, the control terminal is a gate terminal, and the bulk terminal is a body terminal. The first and second current path terminals of the fifth transistor M5 are both coupled to the first current path terminal of the third transistor M3 and to the second current path terminal of the fourth transistor M4. The control terminal of the fifth transistor M5 is coupled to the control terminal of the second transistor M2. The bulk terminal of the fifth transistor M5 is coupled to the reference voltage AVss.

The sixth transistor M6 has a first current path terminal, a second current path terminal, a bulk terminal, and a control terminal. In some embodiments, the sixth transistor M6 is a MOSFET transistor of an n-type, and the first current path terminal is a source terminal, the second current path terminal is a drain terminal, the control terminal is a gate terminal, and the bulk terminal is a body terminal. The first and second current path terminals of the sixth transistor M6 are both coupled to the first current path terminal of the first transistor M1 and to the second current path terminal of the second transistor M2. The control terminal of the sixth transistor M6 is coupled to the control terminal of the fourth transistor M4. The bulk terminal of the sixth transistor M6 is coupled to the reference voltage AVss.

The fifth and sixth transistors M5, M6 form the third transistor pair and can be configured to cancel unwanted capacitance from the second and fourth transistors M2, M4. The fifth and sixth transistors M5, M6 can aid in maintaining consistent gain, linearity, and symmetry at the first and second output terminals Vop, Vom. The third transistor pair in conjunction with the first and second transistor pairs can enhance the common-mode rejection ratio (CMRR), minimize distortion, and improve amplifier performance in wideband applications.

The circuit 200 further includes a first resistor 202 and a second resistor 204. The first resistor 202 has a first terminal and a second terminal. The first terminal of the first resistor 202 is coupled to the bulk terminal of the first transistor M1 and the second terminal of the first resistor 202 is coupled to the reference voltage AVss. The second resistor 204 has a first terminal and a second terminal. The first terminal of the second resistor 204 is coupled to the bulk terminal of the third transistor M3 and the second terminal of the second resistor 204 is coupled to the reference voltage AVss.

The first and second resistors 202, 204 connect bulk terminals of the first and second transistor pairs to the reference voltage AVss, and accordingly, current from the bulk terminals are coupled through the first and second resistors.

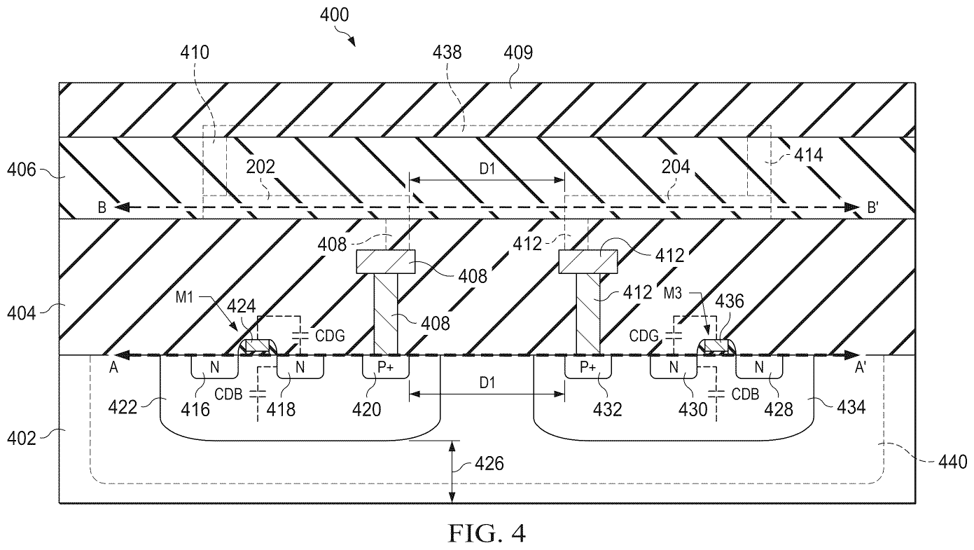

In the context of the amplifier 110 of FIG. 1, the first and second resistors 202, 204 may advantageously help mitigate the off-state capacitive loading effects introduced by the CDB (drain-bulk capacitance) and CDG (gate-drain capacitance) of the first and third transistors M1, M3 (as illustrated in FIG. 4). In a port-combined transceiver architecture, the transistor pairs that are in an off-state remain electrically coupled to the antenna terminal 116 shared between the Tx circuitry 102 and the Rx circuitry 104, even when amplifier 110 is inactive. This coupling presents parasitic capacitive loads that can impact the impedance of the Rx circuitry 104. These parasitic capacitances can degrade the LNA performance by increasing insertion loss, introducing impedance mismatch, narrowing bandwidth, and reducing gain, particularly in high-frequency bands such as in the 5-13 GHz range, such as in the 5-7 GHz range.

The off-state capacitive loading from CDB and CDG is manifest as an impedance seen at the antenna terminal 116 and makes wideband impedance matching challenging. By introducing the first and second resistors 202, 204 in the bulk terminal coupling paths of the first and third transistors M1, M3 to the reference voltage AVss, the path for high-frequency signals through the bulk terminals is modified, effectively increasing series resistance and thereby de-Qing the CDB resonance (such as reducing or dampening the Q-factor of the CDB resonance). This additional resistance may limit the flow of high-frequency currents through the bulk terminal, which may reduce the effective CDB and minimize its loading effect at the shared node. Consequently, the insertion loss is decreased, and the impedance presented to the LNA input may be improved. Additionally, the first and second resistors 202, 204 may help mitigate the impact of CDG by ensuring that the bulk terminals do not serve as a low-impedance ground reference, preserving the high output impedance of the first and second transistor pairs and enhancing wideband performance. As discussed further herein, this approach may be particularly beneficial in a standard n-well process (e.g., without deep n-well or deep p-well). Shallow isolation techniques achieve the above benefits without relying on isolation techniques in a deep n-well processes that have additional processing steps during fabrication that may increase cost. Accordingly, some embodiments may advantageously reduce cost and space.

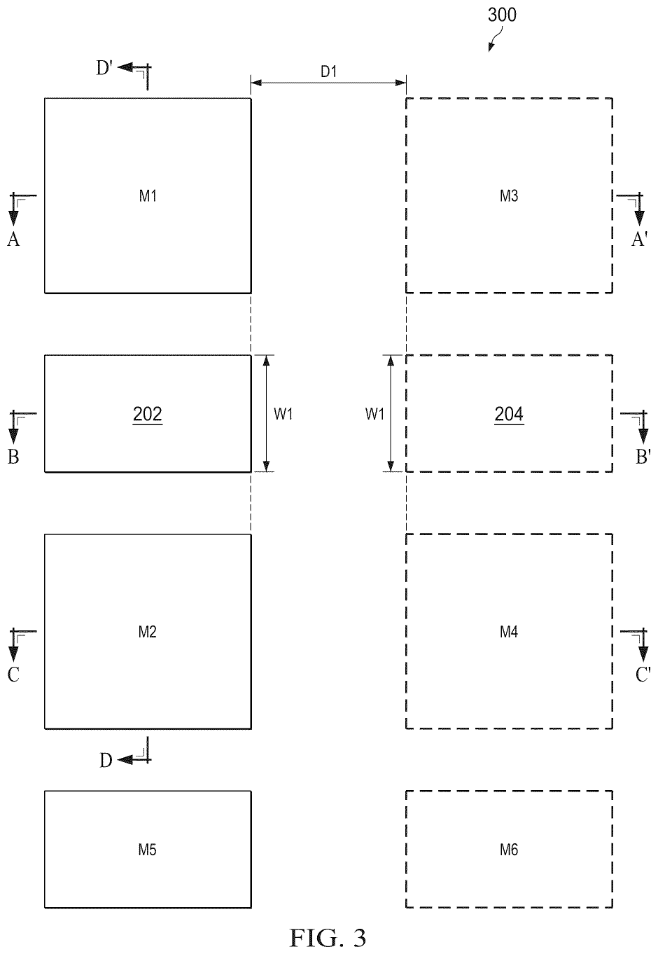

FIG. 3 shows a top view 300 of amplifier 110 devices with resistors coupled between bulk terminals of transistors and a reference voltage.

The top view 300 illustrates how the transistors and resistors of FIG. 2 may be arranged from a layout perspective, according to some embodiments. In some embodiments, the transistors are arranged with sufficient isolation from one another such that the resistors dampen the Q-factor of parasitic capacitance of the first and third transistors M1, M3.

The first resistor 202 is disposed between the first and second transistors M1, M2 in a first direction (shown as the line D-D′). The second transistor M2 is disposed between the first resistor 202 and the fifth transistors M5 in the first direction. The second resistor 204 is disposed between the third and the fourth transistors M3, M4 in the first direction. The fourth transistors M4 is disposed between the second resistor 204 and the sixth transistors M6 in the first direction. The first resistor 202 and the first, second, and fifth transistors M1, M2, M5 are laterally offset from the second resistor 204 and the third, fourth, and sixth transistors M3, M4, M6 in a second direction (shown as the line A-A′) that is perpendicular relative to the first direction. The first transistor and the second transistor M1, M2 are each laterally offset respectively from the third and fourth transistors M3, M4 by a first distance D1 in the second direction. In some embodiments, the fifth transistor M5 is laterally offset from the sixth transistor M6 by the first distance D1 in the second direction. The first distance D1 is determined such that an impedance within a semiconductor substrate between the first and third transistors M1, M3, or between the second and fourth transistors M2, M4, is greater than or equal to an impedance of the first or second resistors 202, 204. In some embodiments, the impedance of the first or second resistors 202, 204 is related to a width W1 of the first or second resistors 202, 204 and in the first direction. The width W1 of the first and second resistors 202, 204 can be less than the first distance D1.

In some embodiments, the width W1 is approximately half of the distance D1. In some embodiments, the width W1 is approximately 10 micrometers (μm) to 25 μm, or approximately 5 μm to 30 μm, greater than approximately 10 μm, or approximately 15 μm. Other values may be used.

Thus, a value of an impedance (or resistance) of one or more of the first or second resistors 202, 204 is based on the first distance D1. In some embodiments, the resistance of the first or second resistors 202, 204 is approximately 20 Ohms to 40 Ohms, approximately 10 Ohms to 50 Ohms, approximately 30 to 100 Ohms, greater than 20 Ohms, or approximately 30 Ohms. Accordingly, crosstalk between the transistors may be mitigate and voltage or current from the first and third transistors M1, M3 couples respectively through the first and second resistors 202, 204 (rather than through the semiconductor substrate and generating cross-talk through adjacent transistors), thereby reducing the capacitive loading of the amplifier as seen by the LNA of the Rx circuitry 104 of FIG. 1.

FIG. 4 illustrates a cross-sectional view 400 of a semiconductor device with one or more transistors and associated resistors.

Cross-sectional view 400 shows cross-sections at a line A-A′ and a line B-B′ from FIG. 3. At line A-A′, a cross-section of the first transistor M1 and the third transistor M3 are shown. At line B-B′, a cross-section of the first resistor 202 and the second resistor 204 are shown. The first transistor M1 is disposed in or above a semiconductor substrate 402. The first transistor M1 has a first current path terminal 416, a second current path terminal 418, a bulk terminal 420, and a well region 422 that are disposed within the semiconductor substrate 402. The first transistor M1 has a control terminal 424 within a first dielectric layer 404 that is disposed on the semiconductor substrate 402.

The first transistor M1 and other transistors discussed herein are shown as n-type MOSFET transistors. For example, the semiconductor substrate 402 can be p-type having a p-type bulk doping. The first current path terminal 416 can be an n-doped source terminal, the second current path terminal 418 can be an n-doped drain terminal, the bulk terminal 420 can be a p-doped body terminal, and the well region 422 can be p-doped. In some embodiments, the bulk terminal 420 has a higher doping concentration than a doping concentration of the semiconductor substrate 402 and the well region 422. In some embodiments, the well region 422 can have a higher doping concentration than the doping concentration of the semiconductor substrate 402. However, it is understood that the transistors discussed herein can alternatively be a p-type MOSFET (not shown), or another transistor type. Also, as discussed previously, transistors shown in the cross-sections herein have single well regions (or shallow wells), and do not have a deep well (such as a deep n-well well below the p-well). That is, in a region 426 from a bottom region of the well region 422 to the bottom surface of the semiconductor substrate 402, the region 426 comprises a light p-type doping or the same doping concentration as the semiconductor substrate 402. Accordingly, in some embodiments, the transistors discussed herein can be formed by low-cost processes while isolation between the transistors can be achieved with the first distance D1 between the first transistor pair and the second transistor pair. Compared to other technologies that include a deep n-well 440 in the substrate, the illustrated single well region of FIG. 4 without a deep n-well 440 may save extra masks and/or doping operations (such as ion implantations), and thereby may advantageously simplify the manufacturing process.

The third transistor M3 is disposed in or above the semiconductor substrate 402. The third transistor M3 has a first current path terminal 430, a second current path terminal 428, a bulk terminal 432, and a well region 434 that are disposed within the semiconductor substrate 402. The third transistor M3 has a control terminal 436 disposed within the first dielectric layer 404. Parasitic capacitances of the first and third transistors M1, M3 are shown as CDG from the drain to the gate of the transistors, and CDB from the drain to the body of the transistors (as discussed in accordance with FIG. 2).

The first resistor 202 and the second resistor 204 are disposed in a second dielectric layer 406 over the first and third transistor M1, M3. The first transistor M1 is coupled to the first resistor 202 by a first interconnect structure 408. The first interconnect structure 408 can include wires or vias in one or more layers of the first dielectric layer 404. The bulk terminal 420 of the first transistor M1 is coupled to the first terminal of the first resistor 202 via the first interconnect structure 408. The third transistor M3 is coupled to the second resistor 204 by a third interconnect structure 412. The third interconnect structure 412 can include wires or vias in one or more layers of the first dielectric layer 404. The bulk terminal 432 of the third transistor M3 is coupled to the first terminal of the second resistor 202 via the third interconnect structure 412.

In some embodiments, the first resistor 202 and the second resistor 204 can be or comprise poly-silicon and can each be poly-silicon resistors. The first and second resistors 202, 204 can be defined by traces within the second dielectric layer 406. The second terminal of the first resistor 202 is coupled to a reference voltage terminal 438 and the second terminal of the second resistor 204 is coupled to the reference voltage terminal 438. In some embodiments, the first resistor 202 is coupled to the reference voltage terminal 438 by a second interconnect structure 410 and the second resistor 204 is coupled to the reference voltage terminal 438 by a fourth interconnect structure 414. The reference voltage terminal 438 can be a wire or trace disposed within a third dielectric layer 409 that is disposed on the second dielectric layer 406. In other embodiments the second terminal of the first resistor is coupled to a first voltage reference terminal and the second terminal of the second resistor is coupled to a second voltage reference terminal. In some embodiments, the first and second voltage reference terminals can have a same potential (such as voltage or ground). The first and second resistors 202, 204 can mitigate the off-state capacitive loading effects of CDB and CDG.

The first and second resistors 202, 204 are separated from one another by the first distance D1 and the first and third transistors M1, M3 are separated from one another by the first distance D1. In some embodiments, the bulk terminal 420 of the first transistor M1 and the bulk terminal 432 of the third transistor M3 are spaced apart from one another within the semiconductor substrate 402 by the first distance D1. In other embodiments the well region 422 of the first transistor M1 and the well region 434 of the third transistor M3 are spaced apart from one another by the first distance D1. In some embodiments, the first distance D1 is approximately 30 μm. In other embodiments, the first distance D1 is approximately 10 μm to 60 μm, or 60 μm to 120 μm, or greater than 60 μm. Other values may be used.

In some embodiments, the first distance D1 is based on a value of the first and second resistors 202, 204 such that isolation is achieved between the first and third transistors M1, M3 and current passes from the bulk terminals 420, 432 and through the first and second resistors 202, 204 to the reference voltage terminal 438.

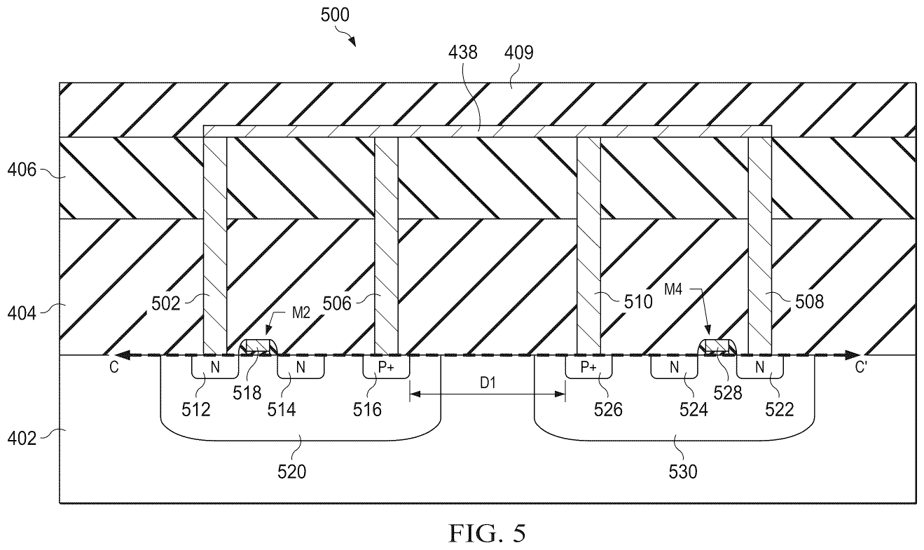

FIG. 5 illustrates a cross-sectional view 500 of a semiconductor device with one or more transistors.

Cross-sectional view 500 shows a cross-section at line C-C′ from FIG. 3. At line C-C′, a cross-section of the second transistors M2 and the fourth transistor M4 are shown. The second transistor M2 is disposed in or above the semiconductor substrate 402. The second transistor M2 has a first current path terminal 512, a second current path terminal 514, a bulk terminal 516, and a well region 520 that are disposed within the semiconductor substrate 402. The second transistor M2 has a control terminal 518 disposed within the first dielectric layer 404 over the semiconductor substrate 402. The fourth transistor M4 is disposed in or above the semiconductor substrate 402. The fourth transistor M4 has a first current path terminal 522, a second current path terminal 524, a bulk terminal 526, and a well region 530 that are disposed within the semiconductor substrate 402. The fourth transistor M4 has a control terminal 528 disposed within the first dielectric layer 404 over the semiconductor substrate 402.

A fifth interconnect structure 502 and a sixth interconnect structure 506 couple the second transistor M2 to the reference voltage terminal 438. The first current path terminal 512 and the bulk terminal 516 of the second transistor M2 are coupled to the reference voltage terminal 438 respectively via the fifth and sixth interconnect structures 502, 506. A seventh interconnect structure 508 and an eighth interconnect structure 510 couple the fourth transistor M4 to the reference voltage terminal 438. The first current path terminal 522 and the bulk terminal 526 of the fourth transistor M4 are coupled to the reference voltage terminal 438 respectively via the seventh and eighth interconnect structures 508, 510.

In some embodiments, the bulk terminal 516 of the second transistor M2 and the bulk terminal 526 of the fourth transistor M4 are spaced apart from one another within the semiconductor substrate 402 by the first distance D1. In other embodiments the well region 520 of the second transistor M2 and the well region 530 of the fourth transistor M4 are spaced apart from one another by the first distance D1. In some embodiments, the first distance D1 is configured such that isolation is achieved between the second and fourth transistors M2, M4.

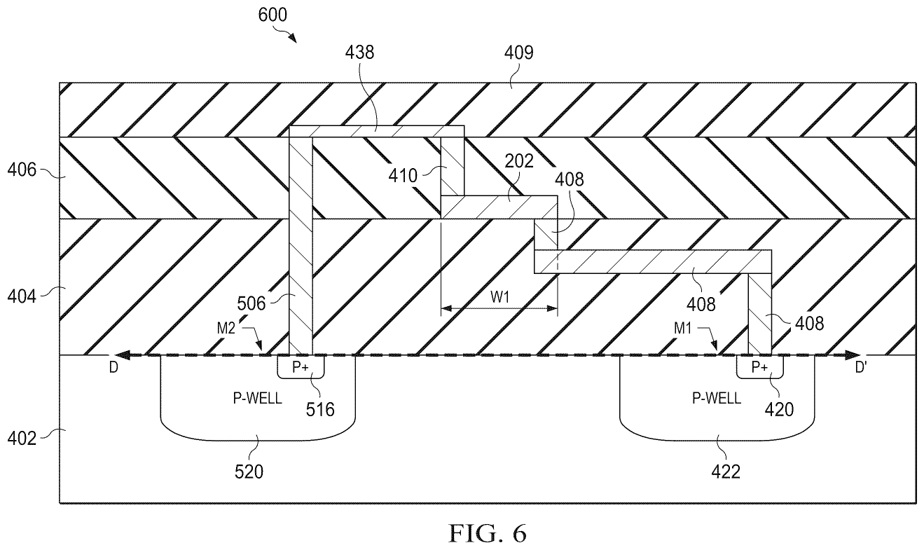

FIG. 6 illustrates a cross-sectional view 600 of a semiconductor device with one or more transistors and associated resistor.

Cross-sectional view 600 shows a cut at a line D-D′ from FIG. 3. At line D-D′, a cross-section through the bulk terminal 420 of the first transistor M1 and through the bulk terminal 516 of the second transistor M2 are shown. The bulk terminal 516 of the second transistor M2 is coupled to the reference voltage terminal 438 by the sixth interconnect structure 506. The bulk terminal 420 of the first transistor M1 is coupled to the first terminal of the first resistor 202 by the first interconnect structure 408. The first resistor 202 has a width W1. The second terminal of the first resistor 202 is coupled to the reference voltage terminal 438 by the second interconnect structure 410.

As discussed in accordance with the first transistor M1 above, the semiconductor substrate 402 can have a doping concentration of a first doping type. The first, second, third, fourth, fifth, and sixth transistors M1, M2, M3, M4, M5, M6 can each have a well region with the first doping type. The doping concentration of the semiconductor substrate 402 extends from a bottom region of the well regions to a bottom surface of the semiconductor substrate 402.

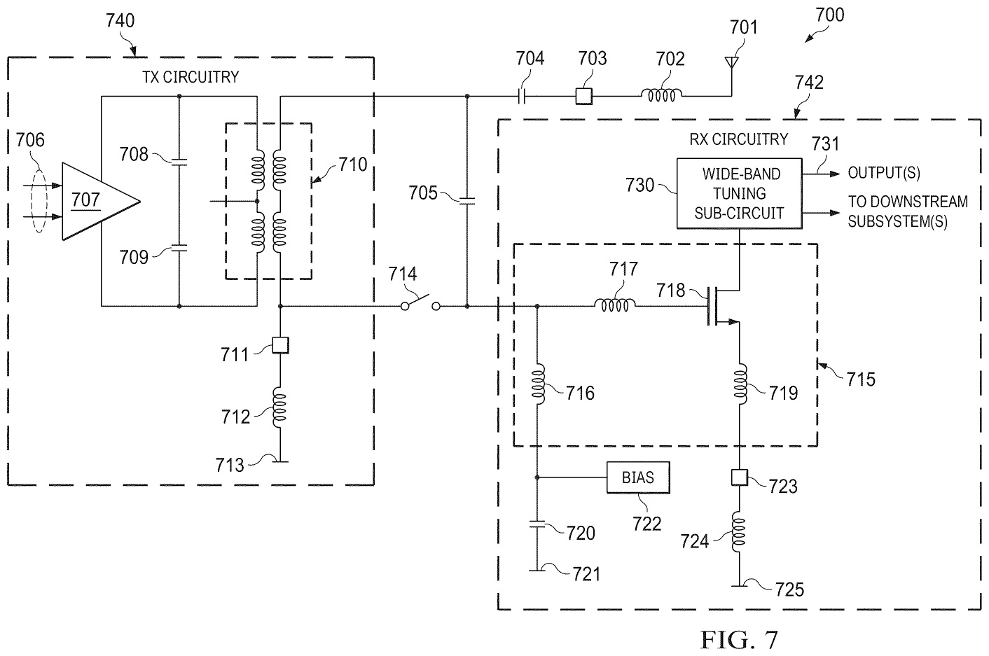

FIG. 7 illustrates a system 700 with an impedance and bandwidth matching system.

FIG. 7 is a reproduction of FIG. 1A from U.S. patent application Ser. No. 18/462,083, entitled “BANDWIDTH TUNING USING SINGLE-INPUT MULTIPLE-OUTPUT LOW-NOISE AMPLIFIER”, filed on Sep. 6, 2023, which is incorporated in its entirety by reference herein. FIG. 7 includes an antenna 701, an amplifier 707, a low-noise amplifier (LNA) sub-circuit 715, and a wide-band tuning sub-circuit 730. The LNA sub-circuit 715 further includes a shunt inductor 716, a capacitor 720, a bias 722, a gate inductor 717, transistor 718, and source inductor 719. Wide-band tuning sub-circuit 730 is fed an impedance-matched signal from LNA sub-circuit 715 and provides outputs 731 to a downstream sub-circuit based on signals provided to components of the wide-band tuning sub-circuit 730.

The antenna 701 of FIG. 7 can correspond to the antenna 106 of FIG. 1. The system 700 includes a Tx circuitry 740 that corresponds to the Tx circuitry 102 of FIG. 1. The Tx circuitry 740 includes the amplifier 707, capacitors 708, 709, and a balun 710 (also referred to as a transformer). The system 700 includes a Rx circuitry 742 that corresponds to the Rx circuitry 104 of FIG. 1. The Rx circuitry 742 includes the receive chain LNA (such as LNA sub-circuit 715 and associated components). The system 700 includes a switch 714 between the Tx circuitry 740 and the Rx circuitry 742. The switch 714 corresponds to the switch 108 of FIG. 1 and provides port combining functionality to the system 700.

System 700 is representative of a circuit capable of receiving a signal from antenna 701, amplifying the signal and matching the impedance of the signal, and outputting a signal at various wide-band bandwidths. For example, system 700 can produce an output signal having a bandwidth between 5-7 GHz or an output signal having a bandwidth.

The system 700 includes an antenna terminal 703 (such as a pin or port that can be an input/output pin or port of a semiconductor chip). The system 700 has a first amplifier (such as LNA of Rx circuitry 742 including LNA sub-circuit 115 and associated circuitry). The second amplifier has an input coupled to the antenna terminal.

The amplifier 707 can also be referred to as a second amplifier 707. The second amplifier 707 has an output coupled to the antenna terminal 703 through the balun 710 and the switch 714. The balun 710 has a first winding coupled to a first differential output terminal (such as of inputs 706 or the first or second output terminal Vop, Vom of FIG. 2). The balun 710 has a second winding that is coupled to the antenna terminal 703. The input of the first amplifier is coupled to the antenna terminal 703 and to the second winding of the balun 710. The switch 714 is coupled between the second winding of the balun 710 and the input of the first amplifier. Thus the output of the second amplifier 707 is coupled to the input of the first amplifier through the balun 710 and the switch 714.

The switch 714 is coupled between the balun 710 and the antenna terminal 703. When the switch 714 is in a closed state, the Tx circuitry 740 can be activated and transmit signals through the antenna 701 through the antenna terminal 703. As such, the system 700 includes a transceiver having a transmit path that includes the second amplifier 707 and a receive path that includes the first amplifier. During a transmit mode of the transceiver, the switch 714 is configured to be closed, the Tx circuitry 740 is activated, and the Rx circuitry 742 is deactivated. During a receive mode of the transceiver, the switch 714 is configured to be open, the Tx circuitry 740 is deactivated (such as the second amplifier is disabled), and the Rx circuitry 742 is activated.

When the switch 714 is in an open state, the Tx circuitry 740 can be deactivated and the first amplifier can be activated in a receive mode where signals received by the antenna 701 are coupled to the second amplifier through the antenna terminal 703.

The second amplifier can include various components in accordance with FIGS. 2-6. For example, the second amplifier 707 can include a first transistor pair (such as the first and second transistors M1, M2) having a first differential input terminal, a first differential output terminal, a first bulk terminal, and a second bulk terminal (see FIG. 2). The first bulk terminal of the first transistor pair can be coupled to a reference voltage terminal (such as reference voltage terminal AVss). The second amplifier 707 can include a second transistor pair (such as the third and fourth transistors M3, M4) coupled in parallel with the first transistor pair having a second differential input terminal, a second differential output terminal, a first bulk terminal, and a second bulk terminal (see FIG. 2). The first bulk terminal of the second transistor pair is coupled to the reference voltage terminal. The first and second differential output terminals are coupled to the balun 710. In some embodiments, the first transistor pair and the second transistor pair are n-type transistors without a deep n-well.

The second amplifier 707 includes a first resistor (such as first resistor 202) having a first terminal coupled to the second bulk terminal of the first transistor pair, and a second terminal coupled to the reference voltage terminal. The second amplifier 707 includes a second resistor (such as second resistor 204) having a first terminal coupled to the second bulk terminal of the second transistor pair, and a second terminal coupled to the reference voltage terminal. In some embodiments, the first and second resistors are defined by poly-silicon traces disposed in a dielectric layer that is disposed above a semiconductor substrate. The second amplifier 707 includes a third transistor pair (such as the fifth and sixth transistors M5, M6 of FIG. 2) coupled between the first transistor pair and the second transistor pair. The third transistor pair is coupled to the first and second resistors through the first transistor pair and the second transistor pair.

Loading effects on the first transistor of the Rx circuitry 742 by the second transistor of the Tx circuitry 740 are minimized by the first and second resistors connected to bulk terminals of the first and second transistor pairs within the second amplifier 707. The first and second resistors, e.g., in combination with layout techniques discussed herein, couples bulk current from the transistor through the resistors before reaching the reference voltage terminal. The resistance may advantageously contribute to a reduction of loading effects from self-capacitance of the transistors, as seen by the Rx circuitry 104, thereby enhancing the operating bandwidth of the Rx circuitry 742.

It is appreciated that reference numerals with the prefix “7” from FIG. 7 correspond to reference numerals with the prefix “1” from FIG. 1A of U.S. patent application Ser. No. 18/462,083. As such, the components/devices/circuit elements/features of FIG. 7 are described in accordance with their corresponding reference numbers in U.S. patent application Ser. No. 18/462,083. Specifically, 700 of FIG. 7 corresponds to 100 of FIG. 1A of U.S. patent application Ser. No. 18/462,083, likewise: 701 corresponds to 101, 702 corresponds to 102, 703 corresponds to 103, 704 corresponds to 104, 705 corresponds to 105, 706 corresponds to 106, 707 corresponds to 107, 708 corresponds to 108, 709 corresponds to 109, 710 corresponds to 110, 711 corresponds to 111, 712 corresponds to 112, 713 corresponds to 113, 714 corresponds to 114, 715 corresponds to 115, 716 corresponds to 116, 717 corresponds to 117, 718 corresponds to 118, 719 corresponds to 119, 720 corresponds to 120, 721 corresponds to 121, 722 corresponds to 122, 723 corresponds to 123, 724 corresponds to 124, 725 corresponds to 125, 730 corresponds to 130 and 731 corresponds to 131.

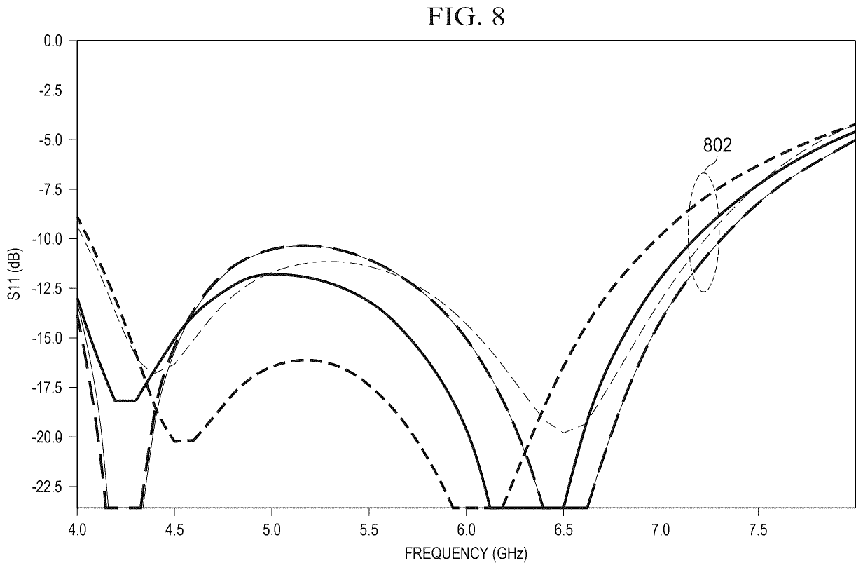

FIG. 8 shows a graph of the simulated reflection coefficient from the system 700 of FIG. 7, implementing 707, e.g., in accordance with FIGS. 2-6, during a receive mode of operation. The reflection coefficient is shown as a magnitude |S11| in a decibel (dB) scale. The reflection coefficient is indicative of how well the first amplifier (such as LNA of the Rx circuitry 742 of FIG. 7) is matched to the antenna 701 during the receive mode while the Tx circuitry is deactivated (such as the |S11| looking in the direction of the inductor 702 from the perspective of the antenna 701). FIG. 8 shows a plurality of S11 curves 802 that represent the reflection coefficient for different gain states and tuning states (such as the tuning states of the wide-band tuning sub-circuit 730) of the LNA. As seen in the plurality of S11 curves 802, during the receive mode, a reflection coefficient of the second amplifier is approximately −10 dB from approximately 4.25 GHz to 7.25 GHz. Accordingly, the first and second resistors of system 700 are effective at minimizing loading effects of the Tx circuitry 740 on the Rx circuitry 742, realizing wide-band coverage applicable to next-generation Wifi applications.

Example embodiments of the present disclosure are summarized here. Other embodiments can also be understood from the entirety of the specification and the claims filed herein.

Example 1. An integrated circuit including: a first transistor disposed in or above a semiconductor substrate and having a control terminal, a first current path terminal, a second current path terminal, and a bulk terminal, where the second current path terminal of the first transistor is coupled to a first differential output terminal of a pair of differential output terminals; a second transistor disposed in or above the semiconductor substrate and having a control terminal, a first current path terminal, a second current path terminal, and a bulk terminal, where the control terminal of the second transistor is coupled to a first differential input terminal of a pair of differential input terminals, where the first current path terminal of the first transistor is coupled to the second current path terminal of the second transistor, and the first current path terminal of the second transistor is coupled to a reference voltage terminal; and a first resistor having a first terminal and a second terminal, where the first terminal of the first resistor is coupled to the bulk terminal of the first transistor, and the second terminal of the first resistor is coupled to the reference voltage terminal, and where the first resistor is disposed in a dielectric layer that is above the first and second transistors.

Example 2. The integrated circuit of example 1, further including: a third transistor disposed in or above the semiconductor substrate and having a control terminal, a first current path terminal, a second current path terminal, and a bulk terminal, where the second current path terminal of the third transistor is coupled to a second differential output terminal of the pair of differential output terminals; and where the bulk terminal of the third transistor is laterally offset from the bulk terminal of the first transistor within the semiconductor substrate by a first distance.

Example 3. The integrated circuit of one of examples 1 or 2, further including: a second resistor having a first terminal and a second terminal, where the first terminal of the second resistor is coupled to the bulk terminal of the third transistor, and the second terminal of the second resistor is coupled to the reference voltage terminal.

Example 4. The integrated circuit of one of examples 1 to 3, where the second resistor is disposed in the dielectric layer, and where the first resistor is laterally offset from the second resistor by at least the first distance.

Example 5. The integrated circuit of one of examples 1 to 4, where a value of an impedance of one or more of the first or second resistors is based on the first distance.

Example 6. The integrated circuit of one of examples 1 to 5, where an impedance within the semiconductor substrate between the first and third transistors is greater than or equal to an impedance of one or more of the first or second resistors.

Example 7. The integrated circuit of one of examples 1 to 6, further including: a fourth transistor disposed in or above the semiconductor substrate and having a control terminal, a first current path terminal, a second current path terminal, and a bulk terminal, where the control terminal of the fourth transistor is coupled to a second differential input terminal of the pair of differential input terminals, where the first current path terminal of the third transistor is coupled to the second current path terminal of the fourth transistor, and the first current path terminal of the fourth transistor is coupled to the reference voltage terminal.

Example 8. The integrated circuit of one of examples 1 to 7, where the bulk terminal of the fourth transistor is laterally offset from the bulk terminal of the second transistor within the semiconductor substrate by at least the first distance.

Example 9. The integrated circuit of one of examples 1 to 8, further including: a fifth transistor disposed in or above the semiconductor substrate and having a control terminal, a first current path terminal, a second current path terminal, and a bulk terminal, where the first and second current path terminals of the fifth transistor are coupled to the first current path terminal of the third transistor, where the bulk terminal of the fifth transistor is coupled to the reference voltage terminal, and where the control terminal of the fifth transistor is coupled to the control terminal of the second transistor.

Example 10. The integrated circuit of one of examples 1 to 9, further including: a sixth transistor disposed in or above the semiconductor substrate and having a control terminal, a first current path terminal, a second current path terminal, and a bulk terminal, where the first and second current path terminals of the sixth transistor are coupled to the second current path terminal of the first transistor, where the bulk terminal of the sixth transistor is coupled to the reference voltage terminal, and where the control terminal of the sixth transistor is coupled to the control terminal of the fourth transistor.

Example 11. The integrated circuit of one of examples 1 to 10, where the first, second, third, fourth, fifth and sixth transistors are metal-oxide-semiconductor field-effect transistors (MOSFETs) of an n-type, and where: the first current path terminal of the first transistor is a source terminal; the second current path terminal of the first transistor is a drain terminal; the control terminal of the first transistor is a gate terminal; the first current path terminal of the second transistor is a source terminal; the second current path terminal of the second transistor is a drain terminal; the control terminal of the second transistor is a gate terminal; the first current path terminal of the third transistor is a source terminal; the second current path terminal of the third transistor is a drain terminal; the control terminal of the third transistor is a gate terminal; the first current path terminal of the fourth transistor is a source terminal; the second current path terminal of the fourth transistor is a drain terminal; the control terminal of the fourth transistor is a gate terminal; the first current path terminal of the fifth transistor is a source terminal; the second current path terminal of the fifth transistor is a drain terminal; the control terminal of the fifth transistor is a gate terminal; the first current path terminal of the sixth transistor is a source terminal; the second current path terminal of the sixth transistor is a drain terminal; and the control terminal of the sixth transistor is a gate terminal.

Example 12. The integrated circuit of one of examples 1 to 11, where, from a top view, the first resistor is disposed between the first and second transistors.

Example 13. The integrated circuit of one of examples 1 to 12, where the bulk terminal of the first transistor is coupled to the first terminal of the first resistor via a first interconnect structure.

Example 14. The integrated circuit of one of examples 1 to 13, where the second terminal of the first resistor is coupled to the reference voltage terminal via a second interconnect structure.

Example 15. The integrated circuit of one of examples 1 to 14, further including: a transformer having a first winding coupled to the first differential output terminal, and a second winding, where a center tap of the first winding is coupled to a supply voltage; an antenna terminal coupled to the second winding of the transformer; and an amplifier having an input coupled to the antenna terminal and to the second winding of the transformer.

Example 16. The integrated circuit of one of examples 1 to 15, where the amplifier is a low-noise amplifier (LNA).

Example 17. The integrated circuit of one of examples 1 to 16, further including a switch coupled between the second winding of the transformer and the input of the amplifier.

Example 18. The integrated circuit of one of examples 1 to 17, where the first resistor is a poly-silicon resistor.

Example 19. An amplifier, including: first and second output terminals; first and second input terminals; a semiconductor substrate; a first transistor disposed in or above the semiconductor substrate and having first and second current path terminals, a bulk terminal, and a control terminal, the second current path terminal of the first transistor coupled to the first output terminal; a second transistor disposed in or above the semiconductor substrate and having first and second current path terminals, a bulk terminal, and a control terminal, where the first current path terminal of the first transistor is coupled to the second current path terminal of the second transistor, and where the control terminal of the second transistor is coupled to the first input terminal; a first resistor disposed in a dielectric layer that is above the semiconductor substrate, the first resistor having a first terminal coupled to the bulk terminal of the first transistor, and a second terminal, where, from a top view, the first resistor is disposed between the first and second transistors in a first direction; a third transistor disposed in or above the semiconductor substrate and having first and second current path terminals, a bulk terminal, and a control terminal, where the control terminal of the third transistor is coupled to the control terminal of the first transistor; a fourth transistor disposed in or above the semiconductor substrate and having first and second current path terminals, a bulk terminal, and a control terminal, where the second current path terminal of the fourth transistor is coupled to the first current path terminal of the third transistor; and a second resistor disposed in the dielectric layer and having a first terminal coupled to the bulk terminal of the third transistor, and a second terminal, where, from the top view, the first resistor is disposed between the third and fourth transistors in the first direction, and where, from the top view and in a second direction perpendicular to the first direction, the first transistor and the second transistor are each laterally offset from the third transistor and the fourth transistor, respectively, by a first distance.

Example 20. The amplifier of example 19, where in the first direction, a width of the first and second resistors is less than the first distance.

Example 21. The amplifier of one of examples 19 or 20, where the second terminal of the first resistor is coupled to a reference voltage terminal and the second terminal of the second resistor is coupled to the reference voltage terminal.

Example 22. The amplifier of one of examples 19 to 21, where the second terminal of the first resistor is coupled to a first voltage reference terminal and the second terminal of the second resistor is coupled to a second voltage reference terminal.

Example 23. The amplifier of one of examples 19 to 22, where the first and second resistors are each poly-silicon resistor defined by traces within the dielectric layer.

Example 24. The amplifier of one of examples 19 to 23, further including: a first interconnect structure, where the bulk terminal of the first transistor is coupled to the first terminal of the first resistor via the first interconnect structure; a second interconnect structure coupling the second terminal of the first resistor to a reference voltage terminal; a third interconnect structure, where the bulk terminal of the third transistor is coupled to the first terminal of the second resistor via the third interconnect structure; and a fourth interconnect structure coupling the second terminal of the second resistor to the reference voltage terminal.

Example 25. The amplifier of one of examples 19 to 24, further including: fifth and sixth interconnect structures, where the first current path terminal and the bulk terminal of the second transistor are coupled to the reference voltage terminal respectively via the fifth and sixth interconnect structures; and a seventh and eighth interconnect structures, where the first current path terminal and the bulk terminal of the fourth transistor are coupled to the reference voltage terminal respectively via the seventh and eighth interconnect structures.

Example 26. The amplifier of one of examples 19 to 25, where an impedance within the semiconductor substrate between the first and third transistors, or between the second and fourth transistors, is greater than an impedance of the first or second resistors.

Example 27. The amplifier of one of examples 19 to 26, further including: a fifth transistor disposed in or above the semiconductor substrate and having first and second current path terminals, a bulk terminal, and a control terminal, where the first and second current path terminals of the fifth transistor are coupled to the first current path terminal of the third transistor and to the second current path terminal of the fourth transistor, and where the control terminal of the fifth transistor is coupled to the control terminal of the second transistor; and a sixth transistor disposed in or above the semiconductor substrate having first and second current path terminals, a bulk terminal, and a control terminal, where the first and second current path terminals of the sixth transistor are coupled to the first current path terminal of the first transistor and to the second current path terminal of the second transistor, and where the control terminal of the sixth transistor is coupled to the control terminal of the fourth transistor, where, from the top view, in the first direction, the second transistor is disposed between the first resistor and the fifth transistor, and the fourth transistor is disposed between the second resistor and the sixth transistor, and, in the second direction, the fifth transistor is laterally offset from the sixth transistor by the first distance.

Example 28. The amplifier of one of examples 19 to 27, where the semiconductor substrate has a doping concentration of a first doping type and the first, second, third, and fourth transistors each have a well region with the first doping type and where the doping concentration of the semiconductor substrate extends from a bottom region of the well regions and extends to a bottom surface of the semiconductor substrate.

Example 29. A circuit including: an antenna terminal; a first amplifier having an input coupled to the antenna terminal; a balun; a switch coupled between the balun and the antenna terminal; and a second amplifier having an output coupled to the antenna terminal through the balun and the switch, and where the output of the second amplifier is coupled to the input of the first amplifier through the balun and the switch, the second amplifier including: a first transistor pair having a first differential input terminal, a first differential output terminal, a first bulk terminal, and a second bulk terminal, where the first bulk terminal of the first transistor pair is coupled to a reference voltage terminal; a second transistor pair coupled to the first transistor pair, the second transistor pair having a second differential input terminal, a second differential output terminal, a first bulk terminal, and a second bulk terminal, where the first bulk terminal of the second transistor pair is coupled to the reference voltage terminal; a first resistor having a first terminal coupled to the second bulk terminal of the first transistor pair, and a second terminal coupled to the reference voltage terminal; and a second resistor having a first terminal coupled to the second bulk terminal of the second transistor pair, and a second terminal coupled to the reference voltage terminal, where the first and second differential output terminals are coupled to the balun.

Example 30. The circuit of example 29, further including a transceiver having a transmit path including the second amplifier, and a receive path including the first amplifier, where: during a transmit mode of the transceiver, the switch is configured to be closed; and during a receive mode of the transceiver, the switch is configured to be open.

Example 31. The circuit of one of examples 29 or 30, where, during the receive mode, a reflection coefficient of the second amplifier is approximately-10 decibels (dB) from 4.25 gigahertz (GHz) to 7.25 GHz.

Example 32. The circuit of one of examples 29 to 31, where, during the receive mode, the second amplifier is disabled.

Example 33. The circuit of one of examples 29 to 32, further including a third transistor pair coupled between the first transistor pair and the second transistor pair, where the third transistor pair is coupled to the first and second resistors through the first transistor pair and the second transistor pair.

Example 34. The circuit of one of examples 29 to 33, where the first transistor pair and the second transistor pair include n-type transistors without a deep n-well.

Example 35. The circuit of one of examples 29 to 34, where the first and second resistors are defined by poly-silicon traces disposed in a dielectric layer that is disposed above a semiconductor substrate, where the first transistor pair and the second transistor pair are disposed in or above the semiconductor substrate.

The above description of illustrated examples, implementations, aspects, etc., of the subject description, including what is described in the Abstract, is not to be exhaustive or to limit the described aspects to the precise forms described. While specific examples, implementations, aspects, etc., are described herein for illustrative purposes, various modifications are possible that are considered within the scope of such examples, implementations, aspects, etc., as those skilled in the relevant art can recognize.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (such as a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” may be understood as one or more circuits that are: (i) incorporated in/over a semiconductor substrate; (ii) incorporated in a single semiconductor package; (iii) incorporated into the same module; and/or (iv) incorporated in/on the same printed circuit board.

Unless otherwise stated, “about,” “approximately,” or “substantially” preceding a value means+/−10 percent of the stated value, or, if the value is zero, a reasonable range of values around zero. Modifications are possible in the described examples, and other implementations are possible, within the scope of the claims.

1. An integrated circuit comprising:
a first transistor disposed in or above a semiconductor substrate and having a control terminal, a first current path terminal, a second current path terminal, and a bulk terminal, wherein the second current path terminal of the first transistor is coupled to a first differential output terminal of a pair of differential output terminals;
a second transistor disposed in or above the semiconductor substrate and having a control terminal, a first current path terminal, a second current path terminal, and a bulk terminal, wherein the control terminal of the second transistor is coupled to a first differential input terminal of a pair of differential input terminals, wherein the first current path terminal of the first transistor is coupled to the second current path terminal of the second transistor, and the first current path terminal of the second transistor is coupled to a reference voltage terminal; and
a first resistor having a first terminal and a second terminal, wherein the first terminal of the first resistor is coupled to the bulk terminal of the first transistor, and the second terminal of the first resistor is coupled to the reference voltage terminal, and wherein the first resistor is disposed in a dielectric layer that is above the first and second transistors.

2. The integrated circuit of claim 1, further comprising:
a third transistor disposed in or above the semiconductor substrate and having a control terminal, a first current path terminal, a second current path terminal, and a bulk terminal, wherein the second current path terminal of the third transistor is coupled to a second differential output terminal of the pair of differential output terminals; and wherein the bulk terminal of the third transistor is laterally offset from the bulk terminal of the first transistor within the semiconductor substrate by a first distance.

3. The integrated circuit of claim 2, further comprising:
a second resistor having a first terminal and a second terminal, wherein the first terminal of the second resistor is coupled to the bulk terminal of the third transistor, and the second terminal of the second resistor is coupled to the reference voltage terminal.

4. The integrated circuit of claim 3, wherein the second resistor is disposed in the dielectric layer, and wherein the first resistor is laterally offset from the second resistor by at least the first distance.

5. The integrated circuit of claim 4, wherein a value of an impedance of one or more of the first or second resistors is based on the first distance.

6. The integrated circuit of claim 4, wherein an impedance within the semiconductor substrate between the first and third transistors is greater than or equal to an impedance of one or more of the first or second resistors.

7. The integrated circuit of claim 3, further comprising:
a fourth transistor disposed in or above the semiconductor substrate and having a control terminal, a first current path terminal, a second current path terminal, and a bulk terminal, wherein the control terminal of the fourth transistor is coupled to a second differential input terminal of the pair of differential input terminals, wherein the first current path terminal of the third transistor is coupled to the second current path terminal of the fourth transistor, and the first current path terminal of the fourth transistor is coupled to the reference voltage terminal.

8. The integrated circuit of claim 7, wherein the bulk terminal of the fourth transistor is laterally offset from the bulk terminal of the second transistor within the semiconductor substrate by at least the first distance.

9. The integrated circuit of claim 7, further comprising:
a fifth transistor disposed in or above the semiconductor substrate and having a control terminal, a first current path terminal, a second current path terminal, and a bulk terminal, wherein the first and second current path terminals of the fifth transistor are coupled to the first current path terminal of the third transistor, wherein the bulk terminal of the fifth transistor is coupled to the reference voltage terminal, and wherein the control terminal of the fifth transistor is coupled to the control terminal of the second transistor.

10. The integrated circuit of claim 9, further comprising:
a sixth transistor disposed in or above the semiconductor substrate and having a control terminal, a first current path terminal, a second current path terminal, and a bulk terminal, wherein the first and second current path terminals of the sixth transistor are coupled to the second current path terminal of the first transistor, wherein the bulk terminal of the sixth transistor is coupled to the reference voltage terminal, and wherein the control terminal of the sixth transistor is coupled to the control terminal of the fourth transistor.

11. The integrated circuit of claim 10, wherein the first, second, third, fourth, fifth and sixth transistors are metal-oxide-semiconductor field-effect transistors (MOSFETs) of an n-type, and wherein:
the first current path terminal of the first transistor is a source terminal;
the second current path terminal of the first transistor is a drain terminal;
the control terminal of the first transistor is a gate terminal;
the first current path terminal of the second transistor is a source terminal;
the second current path terminal of the second transistor is a drain terminal;
the control terminal of the second transistor is a gate terminal;
the first current path terminal of the third transistor is a source terminal;
the second current path terminal of the third transistor is a drain terminal;
the control terminal of the third transistor is a gate terminal;
the first current path terminal of the fourth transistor is a source terminal;
the second current path terminal of the fourth transistor is a drain terminal;
the control terminal of the fourth transistor is a gate terminal;
the first current path terminal of the fifth transistor is a source terminal;
the second current path terminal of the fifth transistor is a drain terminal;
the control terminal of the fifth transistor is a gate terminal;
the first current path terminal of the sixth transistor is a source terminal;
the second current path terminal of the sixth transistor is a drain terminal; and
the control terminal of the sixth transistor is a gate terminal.

12. The integrated circuit of claim 1, wherein, from a top view, the first resistor is disposed between the first and second transistors.

13. The integrated circuit of claim 1, wherein the bulk terminal of the first transistor is coupled to the first terminal of the first resistor via a first interconnect structure.

14. The integrated circuit of claim 13, wherein the second terminal of the first resistor is coupled to the reference voltage terminal via a second interconnect structure.

15. The integrated circuit of claim 1, further comprising:
a transformer having a first winding coupled to the first differential output terminal, and a second winding, wherein a center tap of the first winding is coupled to a supply voltage;
an antenna terminal coupled to the second winding of the transformer; and
an amplifier having an input coupled to the antenna terminal and to the second winding of the transformer.

16. The integrated circuit of claim 15, wherein the amplifier is a low-noise amplifier (LNA).

17. The integrated circuit of claim 15, further comprising a switch coupled between the second winding of the transformer and the input of the amplifier.

18. The integrated circuit of claim 1, wherein the first resistor is a poly-silicon resistor.

19. An amplifier, comprising:
first and second output terminals;
first and second input terminals;
a semiconductor substrate;
a first transistor disposed in or above the semiconductor substrate and having first and second current path terminals, a bulk terminal, and a control terminal, the second current path terminal of the first transistor coupled to the first output terminal;
a second transistor disposed in or above the semiconductor substrate and having first and second current path terminals, a bulk terminal, and a control terminal, wherein the first current path terminal of the first transistor is coupled to the second current path terminal of the second transistor, and wherein the control terminal of the second transistor is coupled to the first input terminal;
a first resistor disposed in a dielectric layer that is above the semiconductor substrate, the first resistor having a first terminal coupled to the bulk terminal of the first transistor, and a second terminal, wherein, from a top view, the first resistor is disposed between the first and second transistors in a first direction;
a third transistor disposed in or above the semiconductor substrate and having first and second current path terminals, a bulk terminal, and a control terminal, wherein the control terminal of the third transistor is coupled to the control terminal of the first transistor;
a fourth transistor disposed in or above the semiconductor substrate and having first and second current path terminals, a bulk terminal, and a control terminal, wherein the second current path terminal of the fourth transistor is coupled to the first current path terminal of the third transistor; and
a second resistor disposed in the dielectric layer and having a first terminal coupled to the bulk terminal of the third transistor, and a second terminal, wherein, from the top view, the first resistor is disposed between the third and fourth transistors in the first direction, and wherein, from the top view and in a second direction perpendicular to the first direction, the first transistor and the second transistor are each laterally offset from the third transistor and the fourth transistor, respectively, by a first distance.

20. A circuit comprising:
an antenna terminal;
a first amplifier having an input coupled to the antenna terminal;
a balun;
a switch coupled between the balun and the antenna terminal; and
a second amplifier having an output coupled to the antenna terminal through the balun and the switch, and wherein the output of the second amplifier is coupled to the input of the first amplifier through the balun and the switch, the second amplifier comprising:
a first transistor pair having a first differential input terminal, a first differential output terminal, a first bulk terminal, and a second bulk terminal, wherein the first bulk terminal of the first transistor pair is coupled to a reference voltage terminal;
a second transistor pair coupled to the first transistor pair, the second transistor pair having a second differential input terminal, a second differential output terminal, a first bulk terminal, and a second bulk terminal, wherein the first bulk terminal of the second transistor pair is coupled to the reference voltage terminal;
a first resistor having a first terminal coupled to the second bulk terminal of the first transistor pair, and a second terminal coupled to the reference voltage terminal; and
a second resistor having a first terminal coupled to the second bulk terminal of the second transistor pair, and a second terminal coupled to the reference voltage terminal, wherein the first and second differential output terminals are coupled to the balun.
